(19) United States
(12) Patent Application Publication
(10) Pub. No.: US 2010/0167455 A1
(43) Pub. Date: Jul. 1, 2010

(54) METHOD FOR FABRICATION OF CMOS IMAGE SENSOR

(76) Inventor: Chung-Kyung Jung, Anyang-si (KR)

Correspondence Address: SHERR & VAUGHN, PLLC, 620 HERNDON PARKWAY, SUITE 320, HERNDON, VA, 20170, US

(21) Appl. No.: 12/642,049

(22) Filed: Dec. 18, 2009

(30) Foreign Application Priority Data
Dec. 29, 2008 (KR) 10-2008-0135286

(51) Int. Cl. H01L 31/0232; C23F 1/08

(52) U.S. Cl. 438/70; 156/345.3; 156/345.19; 257/E31.127

(57) ABSTRACT

Disclosed is a method for fabrication of a CMOS image sensor capable of improving adhesion between an interlayer insulating film and photoresist. According to embodiments in this disclosure, the CMOS image sensor fabrication method may include: forming a plurality of photodiodes over a semiconductor substrate at regular intervals; forming an interlayer insulating film over the semiconductor substrate including the plurality of photodiodes; applying photoresist over the entirety of the interlayer insulating film; hard-baking the photoresist; conducting exposure and development of the photoresist to expose a part of the interlayer insulating film corresponding to the photodiodes, thereby completing a photoresist pattern; and using the photoresist pattern as a mask to selectively etch the exposed part of the interlayer insulating film.

The present application claims priority under 35 U.S.C. 119 to Korean Patent Application No. 10-2008-0135286 (filed on Dec. 29, 2008), which is hereby incorporated by reference in its entirety.

### BACKGROUND

A semiconductor device which converts an optical image into an electrical signal is an image sensor. Semiconductor-based image sensors may be mainly classified into charge coupled device (“CCD”) type image sensors and complementary metal oxide silicon (“CMOS”) type image sensors.

In a CCD, a plurality of photodiodes (“PD”) are arranged in a matrix form to convert an optical signal into an electrical signal. The CCD consists of plural vertical charge coupled devices (“VCCD”), a horizontal charge coupled device (“HCCD”) and a sense amplifier. The plural VCCDs are disposed between vertical PDs aligned in a matrix form, so as to transport charge generated from respective PDs in a vertical direction. The HCCD transports the charge transported by the VCCD in a horizontal direction. The sense amplifier senses the charge transported in the horizontal direction and outputs an electrical signal. However, CCDs are operated using a complicated driving method, exhibit high power consumption, and require a multi-stage photo process. This, in turn, complicates a manufacturing process. The CCD also has disadvantages, including difficulty in integration of a control, signal processing, and an analog/digital (A/D) converter circuits onto a CCD chip. This difficulty with integration leads to difficulty in miniaturization of products.

CMOS image sensors are increasingly seen as next-generation image sensors to overcome the problems with CCDs. CMOS image sensors have a switching mode that uses a control circuit and a signal processing circuit as peripheral circuits. This requires an arrangement of MOS transistors corresponding to the number of unit pixels on a semiconductor substrate. The output of respective unit pixels is detected in sequential order by the MOS transistors. That is, the CMOS image sensor sequentially detects electrical signals from respective unit pixels in a switching mode by arranging a PD and an MOS transistor in each pixel unit, thus capturing an image. The CMOS image sensor has various advantages such as reduced power consumption, a simple manufacturing process with reduced photo-processing steps, etc. as a result of using CMOS fabrication technologies. The CMOS image sensor, which is fabricated by integrating a control circuit, a signal processing circuit and/or an A/D converter in a CMOS image sensor chip, may enable easier miniaturization of products. Accordingly, the CMOS image sensor is now widely used in a variety of applications including, for example, digital still cameras, digital video cameras, etc.

A CMOS image sensor may include a device separator, formed on a semiconductor substrate to define an active region. A photodiode may be formed on a surface of the semiconductor substrate in each unit pixel. A plurality of interlayer insulating films and metal wirings may be placed over the entirety of the semiconductor substrate. A color filter and a micro-lens may be included to collect light.

### SUMMARY

Embodiments relate to a method for fabrication of CMOS image sensors and, more particularly, a method for fabrication of a CMOS image sensor capable of improving adhesion between an interlayer insulating film and photoresist. More particularly, embodiments relate to a method for fabrication of a CMOS image sensor which may include: forming a plurality of photodiodes over a semiconductor substrate at regular intervals; forming an interlayer insulating film over the semiconductor substrate including the plurality of photodiodes; applying photoresist over the entirety of the interlayer insulating film; hard-baking the photoresist; conducting exposure and development of the photoresist to expose a part of the interlayer insulating film corresponding to the photodiodes, thereby completing a photoresist pattern; and using the photoresist pattern as a mask to selectively etch the exposed part of the interlayer insulating film.

Embodiments relate to an apparatus configured to: form a plurality of photodiodes over a semiconductor substrate at regular intervals; form an interlayer insulating film over the semiconductor substrate including the plurality of photodiodes; apply photoresist over the entirety of the interlayer insulating film; hard-bake the photoresist; conduct exposure and development of the photoresist to expose a part of the interlayer insulating film corresponding to the photodiodes, thereby completing a photoresist pattern; and use the photoresist pattern as a mask to selectively etch the exposed part of the interlayer insulating film.

As described above, the inventive method for fabrication of a CMOS image sensor improves adhesion between an interlayer insulating film and photoresist which in turn prevents undercut and, simultaneously, reduces a space between a micro-lens and a photodiode, thereby effectively enhancing efficiency of a CMOS image device.

### DRAWINGS

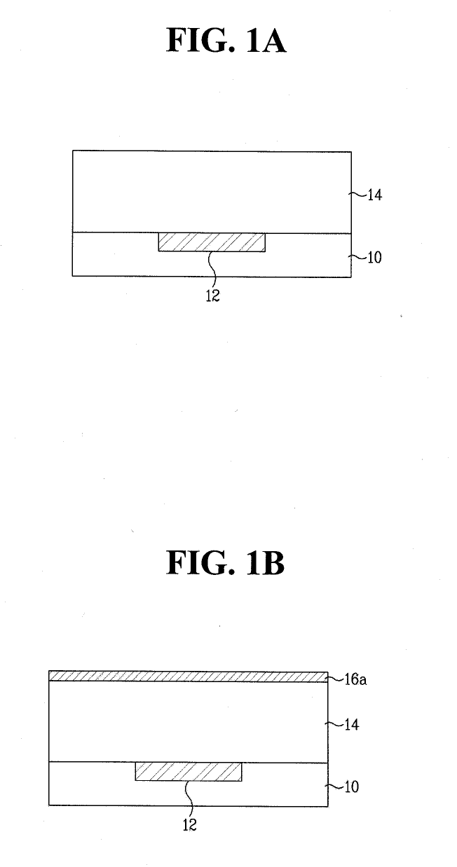

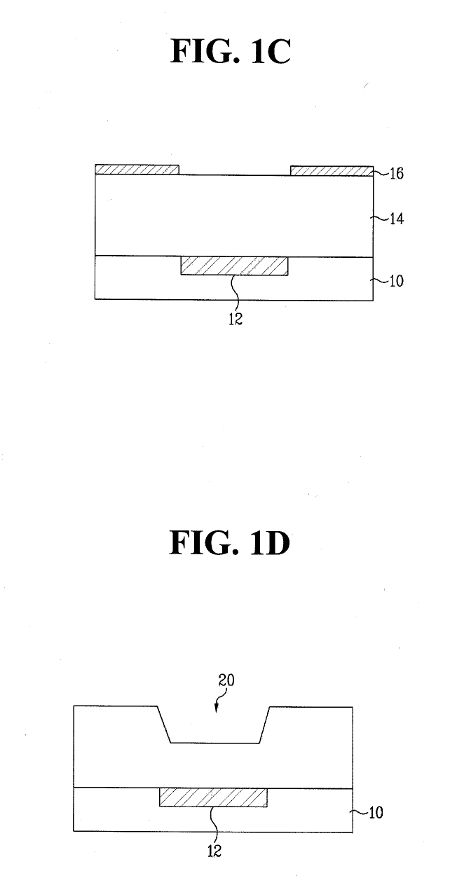

Example FIGS. 1A to 1D are views illustrating a method for fabrication of a CMOS image sensor according to embodiments.

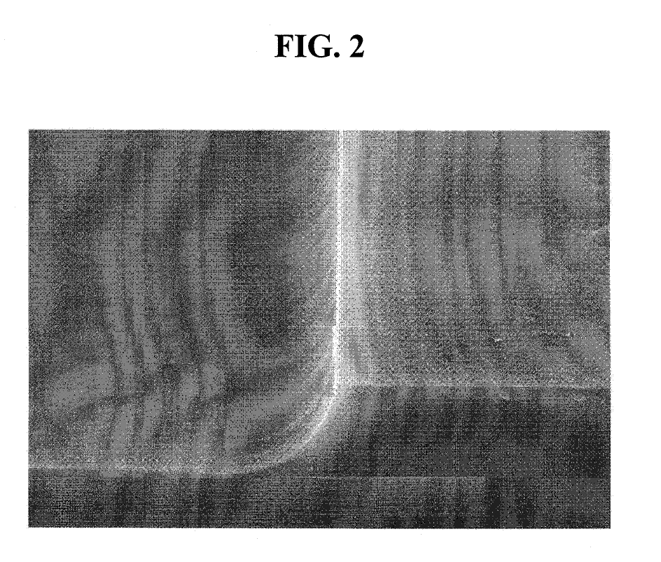

Example FIG. 2 shows a pattern image obtained by hard-baking executed according to embodiments in a method for fabrication of a CMOS image sensor.

### DESCRIPTION

With reference to the accompanying drawings, a method for fabrication of a CMOS image sensor according to embodiments is described in detail below. Example FIGS. 1A to 1D are views illustrating a method for fabrication of a CMOS image sensor according to embodiments.

In example FIGS. 1A to 1D, among a whole CMOS image sensor, only a partial region, which is the subject matter of embodiments, is illustrated. Illustration of the other regions of the sensor having the same configuration as that of related CMOS image sensors will be omitted to avoid repetition where it may make the subject matter of embodiments rather unclear.

Referring to example FIG. 1A, a semiconductor substrate 10 has an active region and a device separator region. To define the active region, a device separator may be formed on the device separator region. In this regard, the device separator may be fabricated by shallow trench isolation (“STI”), local oxidation of silicon (“LOCOS”), etc. Here, an epitaxial process may be conducted over a p++ type semiconductor substrate 10 to grow a first conductive layer with low concentration which in turn forms, for example, a p-type epilayer. The semiconductor substrate 10 used herein may be a single-crystalline silicon substrate. Formation of such an epilayer enables generation of a larger and deeper depletion region in a photodiode which in turn increases a photo-charge collecting ability of a low-voltage photodiode, thus improving photo-sensitivity thereof.

Next, a low concentration impurity may be introduced into the active region between the device separators to form a photodiode 12 inside a surface of the semiconductor substrate 10. Afterward, an interlayer insulating film 14 may be formed throughout the semiconductor substrate 10 having the photodiode 12 and the device separator. Here, the interlayer insulating film 14 may comprise an oxide film such as undoped silicate glass (“USG”) and may be fabricated in a multi-layered form. Inside the interlayer insulating film 14, a variety of wirings may be disposed at constant intervals. Moreover, the semiconductor substrate may further include a shielding layer to prevent light leakage out of the photodiode.

Then, as illustrated in example FIG. 1B, a negative photoresist 16a may be applied to the entirety of the interlayer insulating film 14, followed by hard-baking at approximately 100° C. to 200° C. so as to harden the photoresist 16a. As such, hard-baking the photoresist 16a may increase adhesion between the photoresist 16a and the interlayer insulating film 14 composed of an oxide film.

Therefore, in a process for selectively etching a pixel region of the interlayer insulating film 14 corresponding to the photodiode 12, embodiments reduce space between a micro-lens and the photodiode 12 during a process for manufacturing a CMOS image sensor. Poor adhesion between the photoresist 16a and the interlayer insulating film 14 would allow a chemical solution to flow along an interface between the photoresist 16a and the interlayer insulating film 14, and enter into a gap therebetween, generating undercut. This would cause a problem with photoresist peeling such that photoresist may be stripped from the insulating film due to poor adhesion. However, in embodiments, the process for fabricating a CMOS image sensor executes hard-baking of the photoresist 16a to increase adhesion which in turn simultaneously prevents undercut and photoresist peeling. Referring to example FIG. 2 which shows a pattern image obtained by hard-baking according to embodiments, it was found that strong adhesion serves to prevent undercut and/or photoresist peeling between the photoresist pattern 16 and the interlayer insulating film 14.

As illustrated in example FIG. 1C, the photoresist 16a may be removed by exposure and development to expose a desired portion of the interlayer insulating film 14 corresponding to the photodiode region, thus completing a photoresist pattern 16.

Following this, as illustrated in example FIG. 1D, the completed photoresist pattern 16 may be used as a mask to selectively etch the exposed portion of the interlayer insulating film 14 by a wet etching process using DHF (H₂O:HF=1˜5:1) or BHF, thus generating a trench hole 20. A depth of the trench hole may range from 0.5 to 1.5 μm.

After applying a flammable resist to the interlayer insulating film 14, the coated film may be subjected to exposure and development so as to form a plurality of color filter layers at constant intervals, corresponding to the plural photodiodes 12, wherein the color filter layers filter light at different wavelength ranges.

Subsequently, after application of a micro-lens forming material layer to the entirety of the semiconductor substrate 10 having the foregoing color filter layers, the coated substrate may be subjected to exposure and development so as to conduct patterning of the micro-lens material layer, thus completing a micro-lens pattern over the color filter layer.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A method comprising:
forming a plurality of photodiodes over a semiconductor substrate at regular intervals;
forming an interlayer insulating film over the semiconductor substrate including the plurality of photodiodes;
applying photoresist over the entirety of the interlayer insulating film;
hard-baking the photoresist;
conducting exposure and development of the photoresist to expose a part of the interlayer insulating film corresponding to the photodiodes, thereby completing a photoresist pattern; and
using the photoresist pattern as a mask to selectively etch the exposed part of the interlayer insulating film.

2. The method of claim 1, wherein the hard-baking is conducted at approximately 100° C. to 200° C.

3. The method of claim 1, wherein the photoresist is a negative photoresist.

4. The method of claim 1, wherein the selective etching process using the photoresist pattern as a mask to remove the exposed portion of the interlayer insulating film comprises a wet etching process using BHF.

5. The method of claim 1, wherein the selective etching process using the photoresist pattern as a mask to remove the exposed portion of the interlayer insulating film comprises a wet etching process using DHF.

6. The method of claim 5, wherein the DHF contains H₂O and HF in a relative ratio of H₂O:HF of between approximately 1:1 and 5:1.

7. The method of claim 1, including placing a plurality of color filter layers over the interlayer insulating film at constant intervals corresponding to the plural photodiodes.

8. The method of claim 7, including forming a micro-lens pattern over the color filter layer.

9. The method of claim 1, wherein the selective etching process using the photoresist pattern as a mask to remove the exposed portion of the interlayer insulating film includes formation of a trench hole over the exposed interlayer insulating film portion.

10. The method of claim 9, wherein a depth of the formed trench hole ranges from 0.5 to 1.5 μm.

11. An apparatus configured to:
form a plurality of photodiodes over a semiconductor substrate at regular intervals;
form an interlayer insulating film over the semiconductor substrate including the plurality of photodiodes;
apply photoresist over the entirety of the interlayer insulating film;
hard-bake the photoresist;
conduct exposure and development of the photoresist to expose a part of the interlayer insulating film corresponding to the photodiodes, thereby completing a photoresist pattern; and
use the photoresist pattern as a mask to selectively etch the exposed part of the interlayer insulating film.

12. The method of claim 11, configured to conduct the hard-baking at approximately 100° C. to 200° C.

13. The method of claim 11, configured to apply a negative photoresist.

14. The method of claim 11, configured to use a wet selective etching process using the photoresist pattern as a mask to remove the exposed portion of the interlayer insulating film using BHF.

15. The method of claim 11, configured to use a wet selective etching process using the photoresist pattern as a mask to remove the exposed portion of the interlayer insulating film using DHF.

16. The method of claim 15, configured with DHF which contains H₂O and HF in a relative ratio of H₂O:HF of between approximately 1:1 and 5:1.

17. The method of claim 11, configured to place a plurality of color filter layers over the interlayer insulating film at constant intervals corresponding to the plural photodiodes.

18. The method of claim 17, configured to form a micro-lens pattern over the color filter layer.

19. The method of claim 11, configured to form a trench hole over the exposed interlayer insulating film portion in the selective etching process using the photoresist pattern as a mask to remove the exposed portion of the interlayer insulating film.

20. The method of claim 19, configured to form a trench hole with a depth which ranges from 0.5 to 1.5 μm.
